(19) United States
(12) Patent Application Publication
(10) Pub. No.: US 2025/0008817 A1
(43) Pub. Date: Jan. 2, 2025

(54) Display Device and Mobility to which Display Device is Applied

(71) Applicant: LG Display Co., Ltd., Seoul (KR)

(72) Inventors: Wontae Kim, Paju-si (KR); Sehwan Jeon, Paju-si (KR)

(21) Appl. No.: 18/670,567

(22) Filed: May 21, 2024

(30) Foreign Application Priority Data
Jun. 27, 2023 (KR) 10-2023-0082559

(51) Int. Cl. H10K 59/80

(52) U.S. Cl. CPC H10K 59/873; H10K 59/8792

(57) ABSTRACT

An occurrence of mura at an edge of a screen of a display device and an increase in a temperature of the display device may be prevented, thereby increasing the lifetime of the display device. A display device may include a display panel including a display area a non-display area, and a cover member disposed on the display panel, wherein the cover member includes a first cover and a second cover that are coupled, a light blocking layer disposed between the first cover and the second cover to correspond to the non-display area, and a resin layer disposed between the first cover and the second cover to correspond to the display area.

### CROSS REFERENCE TO RELATED APPLICATION

The present application claims priority to Republic of Korea Patent Application No. 10-2023-0082559, filed on Jun. 27, 2023, which is incorporated by reference in its entirety.

### BACKGROUND

### Field of Technology

The present specification relates to a display device and a mobility to which the display device is applied, and more specifically, to a display device in which a lifetime can be increased and environment/social/governance (ESG) can be achieved by preventing or at least reducing the occurrence of mura at an edge of a screen of the display device and preventing an increase in temperature of the display device, and a mobility to which the display device is applied.

### Description of the Related Art

As the information society develops, the demand for display devices for displaying images is increasing in various forms. Therefore, recently, various display devices, such as liquid crystal display (LCD) devices, plasma display panel (PDP) display devices, quantum dot light emitting display (QLED) device, and organic light emitting diode (OLED) display device, have been utilized.

In particular, the organic light emitting diode display device is attracting attention as a next-generation display device because it is advantageous in terms of power consumption due to low-voltage driving and has excellent color reproduction, a higher response time, a wider viewing angle, and a higher contrast ratio due to the use of an organic light emitting diode display panel.

Recently, research on the application of various display devices, such as an organic light emitting diode display device, to mobilities such as a vehicle is being actively conducted.

### SUMMARY

The present specification is directed to providing a display device and a mobility, in which the clarity of image quality of the display device can be improved by minimizing or at least reducing image quality distortion at an edge of an active area of the display device.

In addition, the present specification is directed to providing a display device and a mobility, in which a lifetime can be increased and reliability can be improved by reducing a surface temperature of the display device and preventing or at least reducing the surface temperature from being transferred into a display panel.

In addition, the present specification is directed to providing a display device and a mobility, in which real black visibility is provided in an OFF state.

The present specification is also directed to providing a display device and a mobility to which the display device is applied, in which environment/social/governance (ESG) can be achieved by reducing the generation of greenhouse gases or carbon emission, which may be caused by a manufacturing process for producing a new display device by increasing the lifetime of the display device.

The objects according to embodiments of the present specification are not limited to the above-described objects, and other objects that are not mentioned will be able to be clearly understood by those skilled in the art to which the present specification pertains from the following description.

A display device according to one embodiment of the present specification includes a display panel including a display area a non-display area, and a cover member disposed on the display panel, wherein the cover member includes a first cover and a second cover that are coupled, a light blocking layer disposed between the first cover and the second cover to correspond to the non-display area, and a resin layer disposed between the first cover and the second cover to correspond to the display area.

A mobility according to one embodiment of the present specification includes a display panel including a display area and a non-display area, and a cover member including a first cover and a second cover bonded by the resin layer and a light blocking layer disposed between the first cover and the second cover on the display panel, wherein the light blocking layer has a structure in which a plurality of layers are stacked and includes colored ink different from black.

A thickness of the first cover may be greater than or equal to a thickness of the second cover.

The light blocking layer may be formed in a stacking structure of a plurality of layers having different widths in the non-display area.

The plurality of layers having different widths may have a sequential protrusion structure toward the display area, and the protrusion structure may have a reverse staircase shape with respect to an upper surface of the first cover.

The light blocking layer may include one of white, red, blue, and burgundy or combinations thereof.

The first cover may include a plurality of optical control patterns on an upper surface thereof.

The optical control pattern may be disposed in an engraved, grooved, or concaved shape.

The plurality of optical control patterns may be disposed to be spaced at regular distances from each other and have a predetermined inclination.

### BRIEF DESCRIPTION OF THE DRAWINGS

FIG. 1 is a view showing a display device according to an embodiment of the present specification.

FIG. 2 is an exploded perspective view according to an example of the display device shown in FIG. 1 according to an embodiment of the present specification.

FIG. 3 is a view showing a stacking structure according to an example along line A-A′ in FIG. 1 according to an embodiment of the present specification.

FIG. 4 is a view showing a display panel shown in FIG. 2 according to an embodiment of the present specification.

FIG. 5 is a circuit diagram of a sub-pixel applied to the display panel of FIG. 4 according to an embodiment of the present specification.

FIG. 6 is a view showing a stacking structure according to an example of a cover member shown in FIG. 2 according to an embodiment of the present specification.

FIG. 7 is an exploded perspective view of the cover member of FIG. 6 according to an embodiment of the present specification.

FIG. 8A is a view showing a configuration of the cover member according to an example of area B in FIG. 7 according to an embodiment of the present specification.

FIG. 8B is a view showing a configuration of a cover member according to another example of area B in FIG. 7 according to an embodiment of the present specification.

FIG. 8C is a view showing a configuration of a cover member according to still another example of area B in FIG. 7 according to an embodiment of the present specification.

FIG. 9 is an exploded perspective view according to another example of the display device shown in FIG. 1 according to an embodiment of the present specification.

FIG. 10 is a view showing a stacking structure according to another example along line A-A′ in FIG. 1 to which the example of FIG. 9 is applied according to an embodiment of the present specification.

FIG. 11 is an exploded perspective view of the cover member of FIG. 10 according to an embodiment of the present specification.

FIG. 12 is a view for describing still another example of the cover member of FIG. 11 according to an embodiment of the present specification.

FIG. 13 is a view showing an example of a mobility to which the display device according to embodiments of the present specification is applied.

### DETAILED DESCRIPTION

Hereinafter, embodiments of the present specification will be described in detail with reference to the accompanying drawings. The embodiments introduced below are provided as examples so that the spirit of the present specification can be sufficiently conveyed to those skilled in the art. Therefore, the present specification is not limited to the embodiments to be described below and may also be specified in other forms.

In addition, in the drawings, the sizes, thicknesses, etc. of the devices may be exaggerated for convenience. Scales of components illustrated in the drawings differ from the actual scale for convenience of description, and thus are not limited to the scales illustrated in the drawings. The same reference numbers denote the same components throughout the specification.

In addition, in describing the present specification, when it is determined that the detailed description of a related known technology may unnecessarily obscure the gist of the present specification, detailed description thereof will be omitted.

When terms “comprise,” “have,” “include,” etc. described in the present specification are used, other parts may be added. When a component is expressed in the singular, it includes a case in which the component is provided as a plurality of components unless specifically stated otherwise.

When the positional relationship is described, for example, when the positional relationship between two parts is described using the term “on,” “above,” “under,” “next to,” or the like, one or more other parts may be located between the two parts unless the term “immediately” or “directly” is used. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Therefore, the exemplary term “below” may include both downward and upward directions.

In the description of the components of the present specification, terms such as first, second, A, B, (a), and (b) may be used. These terms are only for the purpose of distinguishing one component from another component, and the nature, sequence, order, or the like of the corresponding component is not limited by these terms.

In adding reference numerals to components in each drawing, the same components may have the same reference numerals as much as possible even when they are shown in different drawings. In addition, in the description of the present specification, when it is determined that a detailed description of a related known configuration or function may obscure the gist of the present specification, detailed description thereof may be omitted.

Features of various embodiments of the present specification can be coupled or combined partially or entirely, and various technological interworking and driving are possible, and the embodiments may be implemented independently of each other or implemented together in an associated relationship.

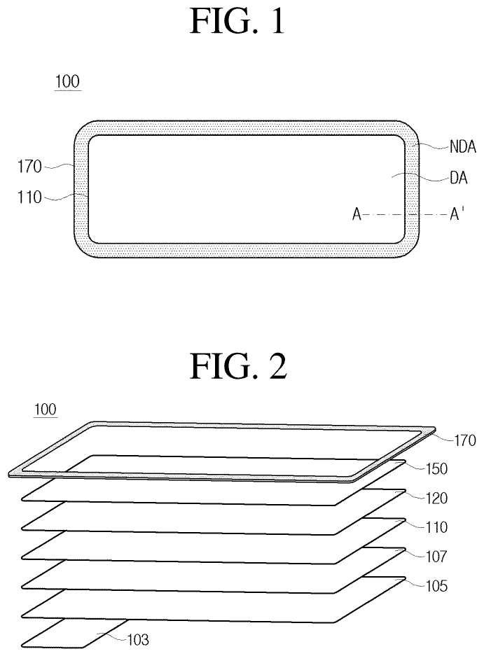

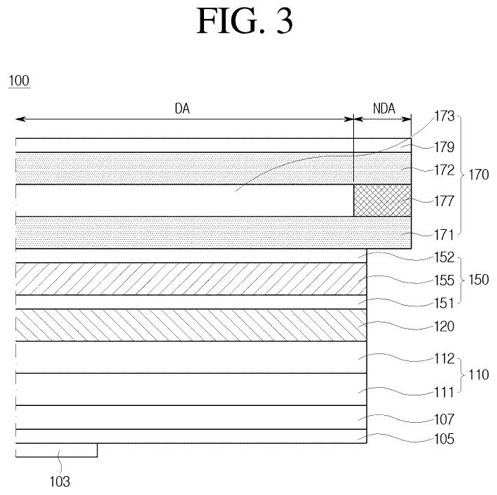

Hereinafter, a display device of the present specification will be described with reference to the accompanying drawings and embodiments as follows. FIG. 1 is a view showing a display device according to an embodiment of the present specification, FIG. 2 is an exploded perspective view according to an example of the display device shown in FIG. 1, and FIG. 3 is a view showing a stacking structure according to an example along line A-A′ in FIG. 1.

In the drawing, an X-axis indicates a direction parallel to a gate line, a Y-axis indicates a direction parallel to a data line, and a Z-axis indicates a height direction of the display device.

A display device 100 according to an embodiment of the present specification implemented as an organic light emitting diode display device will be described mainly, but may also be implemented as a liquid crystal display device, a plasma display panel (PDP) display device, a quantum dot light emitting display (QLED) device, or an electrophoresis display device.

Referring to FIGS. 1 to 3, the display device 100 according to the embodiment of the present specification is partitioned into a display area DA and a non-display area NDA outside the display area DA and includes a display panel 110 and a cover member 170 coupled to the display panel 110. The display device 100 may further include a backplate 107 disposed under the display panel 110, a heat dissipation member 105 disposed under the backplate 107, and a driving circuit member 103. The display device 100 may further include a polarization member 120 disposed on the display panel 110 and an optical adhesive member 150 for coupling the display panel 110 with the cover member 170.

The display panel 110 may include a first substrate 111 and a second substrate 112 that face each other, and a plurality of pixels capable of transmitting incident light or displaying images may be disposed in the display area DA.

The first substrate 111 may be a plastic film, a glass substrate, or a silicon wafer substrate formed using a semiconductor process.

The second substrate 112 may be an encapsulation substrate. The second substrate 112 may be a plastic film, a glass substrate, or an encapsulation film. The first substrate 111 and the second substrate 112 may be made of a transparent material.

The first substrate 111 may be formed to be greater than the second substrate 112, and thus a portion of the first substrate 111 may be exposed without being covered by the second substrate 112.

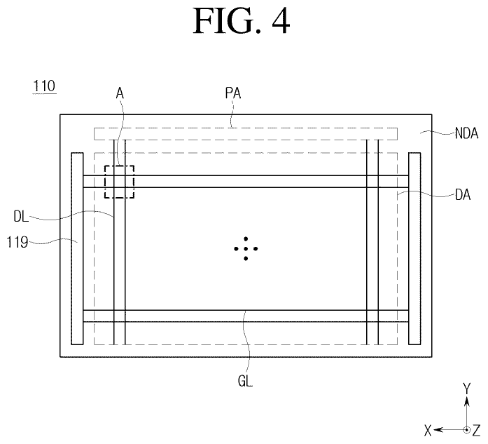

As shown in FIG. 4, the display panel 110 may be partitioned into the display area DA and the non-display area NDA outside the display area DA. The non-display area NDA may be formed in an edge area surrounding the display area DA.

A gate in panel (GIP) unit 119 and a pad unit PA that are a driving unit for driving pixels may be disposed in the non-display area NDA. A plurality of pixels are disposed in the display area DA, and images may be displayed through the pixels.

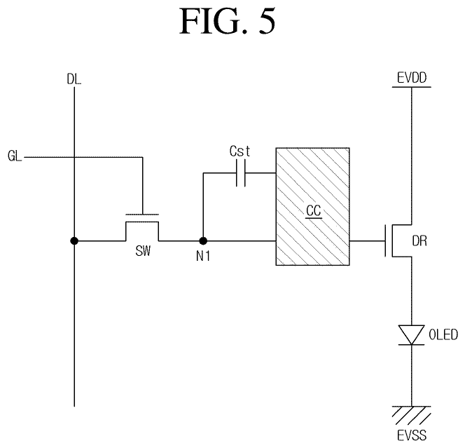

Referring to FIG. 5, one sub-pixel may include a switching transistor SW, a driving transistor DR, a capacitor Cst, a compensation circuit CC, and an organic light emitting diode OLED.

A first electrode (e.g., a drain electrode) of the switching transistor SW is electrically connected to the data line DL, and a second electrode (e.g., a source electrode) thereof is electrically connected to a first node N1. A gate electrode of the switching transistor SW is electrically connected to the gate line GL. The switching transistor SW transmits a data signal supplied through the data line DL to the first node N1 in response to a scan signal supplied through the gate line GL.

The capacitor Cst is electrically connected to the first node N1 to charge a voltage applied to the first node N1.

A first electrode (e.g., a drain electrode) of the driving transistor DR receives a high potential driving voltage EVDD, and a second electrode (e.g., a source electrode) thereof is electrically connected to a first electrode (e.g., an anode electrode) of the organic light emitting diode OLED. The driving transistor DR may control the amount of driving current flowing through the organic light emitting diode OLED in response to a voltage applied to the gate electrode.

Semiconductor layers of the switching transistor SW or/and the driving transistor DR may contain silicon such as a-Si, poly-Si, or low-temperature poly-Si, or oxide such as indium-gallium-zinc-oxide (IGZO), but are not limited thereto.

The organic light emitting diode OLED outputs light corresponding to the driving current. The organic light emitting diode OLED may output light corresponding to any one of red, green, and blue.

The organic light emitting diode OLED may include an anode electrode, a light emitting layer formed on the anode electrode, and a cathode electrode for supplying a common voltage. The light emitting layer may be implemented to emit light of the same color for each pixel, such as white light, or implemented to emit different colors for each pixel, such as red, green, or blue light.

The compensation circuit CC may be provided in the pixel to compensate a threshold voltage of the driving transistor DR. The compensation circuit CC may be formed of one or more transistors. The compensation circuit CC may include one or more transistors and capacitors and may be configured in any of various ways according to a compensation method. The pixel including the compensation circuit CC may have any of various structures such as 3T1C, 4T2C, 5T2C, 6T1C, 6T2C, 7T1C, and 7T2C.

The organic light emitting diode OLED may be disposed in a plurality of light emitting parts, and the plurality of light emitting parts may include a red emission area, a green emission area, and a blue emission area and further include a white emission area.

A circuit element layer is disposed on the first substrate 111 between the first and second substrates 111 and 112. In the circuit element layer, circuit elements including various signal lines, thin film transistors, and capacitors are provided for each pixel. The signal lines may include gate lines, data lines, driving power lines, common power lines, and reference lines, and the thin film transistor may include a switching thin film transistor, a driving thin film transistor, and a sensing thin film transistor.

Referring back to FIGS. 2 and 3, a back plate 107 is disposed under the display panel 110.

The back plate 107 may be coupled to a back surface of the first substrate 111 of the display panel 110 to maintain the rigidity of the display panel 110, prevent or reduce a foreign substance from being attached to a lower portion of the display panel 110, and mitigate an external impact.

The back plate 107 may be implemented as a plastic thin film made of polyimide. Although not shown, the back plate 107 may include an adhesive layer and may be attached to a back surface of the display panel 110.

A heat dissipation member 105 is disposed under the back plate 107.

The heat dissipation member 105 may be coupled to a back surface of the back plate 107 to disperse heat generated from the display panel 110, thereby preventing damage to driving elements of the display panel 110, and more firmly support the display panel 110, thereby protecting the display panel 110 from an external impact. In addition, the heat dissipation member 105 may also serve as a ground for discharging electric charges to the outside.

The heat dissipation member 105 may serve to dissipate heat generated from the driving circuit member 103 disposed under the heat dissipation member 105. The heat dissipation member 105 may be disposed between the display panel 110 and the driving circuit member 103, thereby preventing the heat generated in the driving circuit member 103 from being transferred to the display panel 110.

The heat dissipation member 105 may include a metal material such as aluminum, copper, magnesium, or graphite to dissipate and/or block the heat generated from the display panel 110 and/or the driving circuit member 103, and may be made of a plastic material having excellent thermal conductivity.

The heat dissipation member 105 may be attached to the back surface of the back plate 107 by an adhesive layer included in the back plate 107.

The driving circuit member 103 may be a printed circuit board, a flexible printed circuit board, or a tape printed circuit board to which an IC, such as a data driver or timing controller for driving the display panel 110, is coupled.

As shown in FIGS. 2 and 3, the cover member 170 is disposed on the display panel 110 to protect the display panel 110 from an external impact, etc. The cover member 170 is coupled to the display panel 110 through the optical adhesive member 150.

The cover member 170 may have a structure in which a first cover 171 and a second cover 172 are coupled and include a light blocking layer 177 and a resin layer 173. The cover member 170 may further include a coating layer 179 disposed on the second cover 172.

The cover member 170 serves to protect the display panel 110 and is disposed to be exposed to the outside. The cover member 170 may be disposed to cover the entire surface of the display panel 110 with a greater area than the display panel 110 and may accommodate the display panel 110 therein.

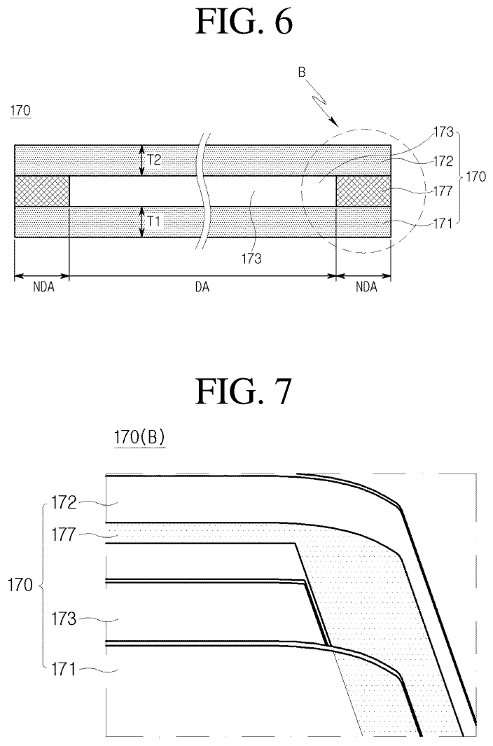

Referring to FIGS. 6 and 7, the cover member 170 may be partitioned into the display area DA and the non-display area NDA, and the display area DA of the cover member 170 is disposed to overlap the display area DA of the display panel 110 to correspond to the display area DA of the display panel 110. Transparent material layers may be disposed in the display area DA of the cover member 170 so that the image generated by the light emitted from the display area DA of the display panel 110 may be visible by a user.

Specifically, since the first cover 171, the resin layer 173, and the second cover 172 may be disposed in a stacking structure in the display area DA of the cover member 170, the user may perceive the images in the display area DA of the display panel 110 through the display area DA of the cover member 170.

The first cover 171 and the second cover 172 may be made of a transparent glass or transparent plastic material. For example, the first cover 171 and the second cover 172 may be a film type including an organic material such as polymethylmethacrylate (PMMA), polycarbonate (PC), cycloolefin polymer (COP), polyethylene terephthalate (P), polyimide (PI), or polyaramid (PA) that has impact resistance and light transmittance and may contain an inorganic material such as thin glass or sapphire.

The resin layer 173 is disposed between the first cover 171 and the second cover 172 of the cover member 170 to bond the first cover 171 and the second cover 172.

The resin layer 173 is disposed in the display area DA of the cover member 170, is in contact with an upper surface of the first cover 171 of the cover member 170, and is in contact with a back surface of the second cover 172 in the display area DA. The resin layer 173 is disposed between the first cover 171 and the second cover 172 to correspond to the display area DA of the display panel 110. The resin layer 173 is disposed to be in contact with a side surface of the light blocking layer 177 at the edge of the display area DA.

The resin layer 173 may contain a transparent resin material. Specifically, the resin layer 173 may contain an ultraviolet (UV) curable acrylic resin or a thermosetting resin.

The non-display area NDA of the cover member 170 is disposed to overlap the non-display area NDA of the display panel 110 to correspond to the non-display area NDA of the display panel 110, and the non-display area NDA of the cover member 170 is disposed to be greater than the non-display area NDA of the display panel 110. The non-display area NDA of the cover member 170 may be referred to as a bezel area.

The non-display area NDA of the cover member 170 is an area surrounding the display area DA. Specifically, as shown in FIG. 1, the non-display area NDA of the cover member 170 is an area adjacent to upper, lower, left, and right sides of the display area DA. Therefore, the non-display area NDA of the cover member 170 includes an upper bezel area adjacent to the upper side of the display area DA and extending from the upper side of the display area DA to an end of the cover member 170, a lower bezel area adjacent to the lower side of the display area DA and extending from the lower side of the display area DA to the end of the cover member 170, a left bezel area adjacent to the left side of the display area DA and extending to the end of the cover member 170, and a right bezel area adjacent to the right side of the display area DA and extending from the right side of the display area DA to the end of the cover member 170.

The light blocking layer 177 is disposed in the non-display area NDA of the cover member 170 to block various circuit elements, lines, components, and other structures for driving the display panel 110 from being visible to the user.

Specifically, as shown in FIGS. 6 and 7, the light blocking layer 177 is disposed to correspond to the non-display area NDA of the cover member 170 between the first cover 171 and the second cover 172. The light blocking layer 177 may be disposed to be in contact with the upper surface of the first cover 171 and the back surface of the second cover 172.

The light blocking layer 177 may be disposed to cover all non-display areas NDA of the display panel 110 excluding the display area DA. Since the display area DA of the display panel 110 corresponds to the display area DA of the cover member 170, the light blocking layer 177 may be disposed to cover the non-display area NDA excluding the display area DA of the cover member 170. The light blocking layer 177 is disposed between the first cover 171 and the second cover 172 to correspond to the non-display area NDA of the display panel 110.

The light blocking layer 177 may be disposed to extend from an outer edge of the display area DA to the end of the cover member 170 between the first cover 171 and the second cover 172. The end of the light blocking layer 177 may be located inward from an outer end of the cover member 170.

In FIG. 7, etc., although a width of the light blocking layer 177 disposed at the upper side of the cover member 170 is shown as being different from a width of the light blocking layer 177 disposed at the right side of the cover member 170, the present disclosure is not limited thereto, and the widths of the light blocking layers 177 disposed at the upper, lower, left, and right sides of the non-display area NDA of the cover member 170 may all be the same. The light blocking layer 177 may also be referred to as an ink layer.

A thickness T1 of the first cover 171 of the cover member 170 may be greater than or equal to a thickness T2 of the second cover 172.

Since the display device 100 according to the present specification adopts the cover member 170 in which the first cover 171 and the second cover 172 are bonded and the light blocking layer is formed between the first cover 171 and the second cover 172 to prevent or at least reduce the occurrence of a step caused by the light blocking layer 177, thereby improving mura or screen distortion at the edge of the display area DA, which may be caused by the step. Therefore, the display device 100 according to the present specification can increase the image clarity of the display device 100.

In addition, the display device 100 according to the present specification may adopt the cover member 170 in which the first cover 171 and the second cover 172 are coupled by the resin layer 173 to prevent a quick increase in a surface temperature of the display device 100 due to the cover member 170 having a structure in which layers having different media are stacked.

In addition, the display device 100 according to the present specification may adopt the cover member 170 in which the first cover 171 and the second cover 172 are coupled by the resin layer 173 to prevent or at least reduce a temperature of an external surface from being transferred to the display panel 110, thereby increasing the lifetime and improving reliability of the display device 100.

In the cover member 170 applied to the display device 100 according to the present specification, the first cover 171 and the second cover 172 may be bonded by arranging the resin layer 173 in the display area DA between the first cover 171 and the second cover 172, and the light blocking layer 177 may be disposed in the non-display area NDA so that the light blocking layer 177 surrounds the resin layer 173, thereby preventing the overflow of the resin layer 173.

The coating layer 179 may be disposed on one surface of the cover member 170. Specifically, the coating layer 179 is disposed on an upper surface of the second cover 172 and exposed to the outside. The coating layer 179 is disposed to cover the display area DA and the non-display area NDA of the cover member 170 to increase the surface rigidity of the cover member 170. The coating layer 179 may contain an anti-fingerprint material and an anti-residue material. The coating layer 179 may perform an anti-fingerprint and anti-residue function.

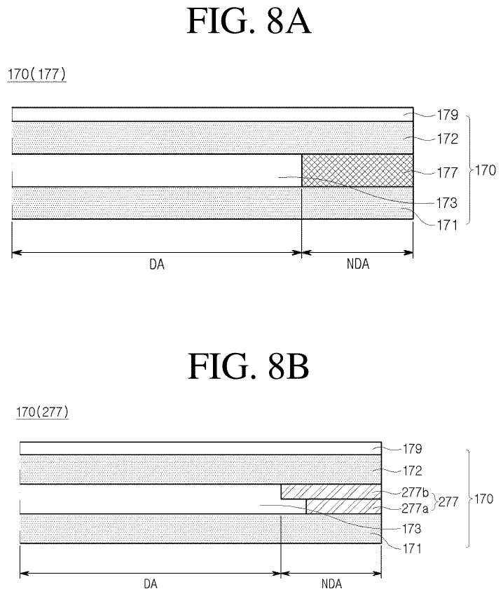

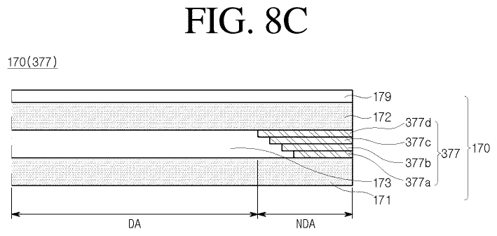

Referring to FIG. 8A, the light blocking layer 177 according to an example of the present specification may be disposed as a single layer in the non-display area NDA between the first cover 171 and the second cover 172. As described above, the resin layer 173 is disposed in the display area DA between the first cover 171 and the second cover 172 so that the first cover 171 and the second cover 172 are coupled through the resin layer.

The resin layer 173 may be in contact with a side surface of the light blocking layer 177 disposed in the non-display area NDA.

Referring to FIG. 8B, the light blocking layer 277 according to another example of the present specification may be disposed in a structure in which a first light blocking layer 277a and a second light blocking layer 277b are stacked as a double layer in the non-display area NDA between the first cover 171 and the second cover 172. A back surface of the first light blocking layer 277a may be in contact with the upper surface of the first cover 171, and an upper surface of the second light blocking layer 277b may be in contact with the back surface of the second cover 172.

A width of the first light blocking layer 277a may differ from a width of the second light blocking layer 277b. The width of the first light blocking layer 277a may be smaller than the width of the second light blocking layer 277b, and the stacked structure of the first light blocking layer 277a and the second light blocking layer 277b may have a staircase structure. The staircase structure may have a reverse staircase shape with respect to the upper surface of the first cover 171.

Specifically, the second light blocking layer 277b may be disposed in a structure that protrudes toward the display area DA more than the first light blocking layer 277a. One end of the first light blocking layer 277a may be disposed to be located inside one end of the second light blocking layer 277b. Here, the inside indicates a direction from the edge of the display area DA toward the end or edge of the cover member 170 or the area in which the light blocking layer 170 is disposed.

The other end of the first light blocking layer 277a and the other end of the second light blocking layer 277b may be disposed to match the other end of any one of the cover member 170, the first cover 171, and the second cover 172.

In this case, the resin layer 173 may be disposed to extend from the display area DA to the non-display area NDA of the cover member 170. The resin layer 173 may be disposed to be in contact with one end of the first light blocking layer 277a and to be in contact with at least portions of one end and the back surface of the second light blocking layer 277b. With this structure, the first cover 171 and the second cover 172 can be prevented from being peeled off or disassembled.

Referring to FIG. 8C, a light blocking layer 377 according to still another example of the present specification may be disposed in a structure in which a first light blocking layer 377a, a second light blocking layer 377b, a third light blocking layer 377c, and a fourth light blocking layer 377d are stacked as a quadruple layer in the non-display area NDA between the first cover 171 and the second cover 172. A back surface of the first light blocking layer 377a may be in contact with the upper surface of the first cover 171, and an upper surface of the fourth light blocking layer 377d may be in contact with the back surface of the second cover 172.

A width of the first light blocking layer 377a may differ from a width of the second light blocking layer 377b. The width of the second light blocking layer 377b may differ from a width of the third light blocking layer 377c. The width of the third light blocking layer 377c may differ from a width of the fourth light blocking layer 377d.

In the multi-stacking structure of the light blocking layer 377, the uppermost layer may have the greatest width, and the lowest layer may have the smallest width. For example, the width of the third light blocking layer 377c may be smaller than the width of the fourth light blocking layer 377d, the width of the second light blocking layer 377b may be smaller than the width of the third light blocking layer 377c, and the width of the first light blocking layer 377a may be smaller than the width of the second light blocking layer 377b.

The stacking structure of the first light blocking layer 377a, the second light blocking layer 377b, the third light blocking layer 377c, and the fourth light blocking layer 377d may have a staircase structure. The staircase structure may have a reverse staircase shape with respect to the upper surface of the first cover 171.

Specifically, the fourth light blocking layer 377d may be disposed in a structure that protrudes toward the display area DA more than the third light blocking layer 377c. The third light blocking layer 377c may be disposed in a structure that protrudes toward the display area DA more than the second light blocking layer 377b. The second light blocking layer 377b may be disposed in a structure that protrudes toward the display area DA more than the first light blocking layer 377a.

One end of the first light blocking layer 377a may be disposed to be located inside one end of the second light blocking layer 377b, the one end of the second light blocking layer 377b may be disposed to be located inside one end of the third light blocking layer 377c, and the one end of the third light blocking layer 377c may be disposed to be located inside one end of the fourth light blocking layer 377d.

Here, the inside indicates a direction from the edge of the display area DA toward the end or edge of the cover member 170 or the area in which the light blocking layer 377 is disposed. Due to the sequential protruding structures of the first to fourth light blocking layers, the side surface of the light blocking layer 377 in which multiple layers are stacked may have an inclined structure. Here, the protruding direction of the protruding structure indicates a direction toward the display area DA.

The other end of the first light blocking layer 377a, the other end of the second light blocking layer 377b, the other end of the third light blocking layer 377c, and the other end of the fourth light blocking layer 377d may be disposed to match the other end of any one of the first cover 171 and the second cover 172.

In this case, the resin layer 173 may be disposed to extend from the display area DA to the non-display area NDA of the cover member 170. The resin layer 173 may be disposed to be in contact with one end of the first light blocking layer 377a and to be in contact with at least portions of one end and the back surface of the second light blocking layer 277b. In addition, the resin layer 173 may be disposed to be in contact with at least portions of one end and the back surface of the third light blocking layer 377c and to be in contact with at least portions of one end and the back surface of the fourth light blocking layer 377d.

With this structure, the first cover 171 and the second cover 172 can be prevented or at least reduced from being peeled off or disassembled.

One end and the other end described herein may include side surfaces of specific layers or specific structures.

The light blocking layers 177, 277, and 377 disclosed in the embodiments of the present specification may be opaque layers such as black ink (e.g., a polymer filled with carbon black) or opaque layers containing a color other than black.

For example, when the light blocking layer is provided as a colored ink layer, a light blocking layer with multiple layers stacked may be applied to implement actual black or block reflected light or external light, and in this case, a step may occur depending on the number of stacked layers.

In the display device 100 according to the embodiments of the present specification, the light blocking layers 177, 277, and 377 are disposed between the first cover 171 and the second cover 172, and thus no step occurs even when the plurality of layers are stacked. Therefore, it is possible to prevent screen mura or image quality distortion due to the step at the edge of the display area DA, and colored light blocking layers may be applied.

The light blocking layers 277 and 377 according to one embodiment may include at least some of light blocking layers including one of white, black, red, blue, and burgundy, or a combination of the colors.

In the display device 100 according to the present specification, the inside between the first cover 171 and the second cover 172 may be filled with the resin layer 173, thereby preventing the occurrence of the air gap inside the cover member 170 and preventing the occurrence of screen mura by planarizing the possible step. The resin layer 173 of the cover member 170 may bond the first cover 171 and the second cover 172 to minimize or at least reduce the shattering of the cover member 170 when the display device 100 is damaged, thereby preventing harm to the user.

The cover member 170 is coupled to the display panel 110 through the optical adhesive member 150 as shown in FIGS. 2 and 3. Specifically, the back surface of the first cover 171 of the cover member 170 and the upper surface of the second substrate 112 of the display panel 110 are coupled through the optical adhesive member 150.

The optical adhesive member 150 includes a first optical adhesive layer 151, a second optical adhesive layer 152, and an optical control layer 155 disposed between the first optical adhesive layer 151 and the second optical adhesive layer.

The first optical adhesive layer 151 couples the optical control layer 155 with the polarization member 120 and the display panel 110 that are disposed under the optical adhesive member 150, and the second optical adhesive layer 152 couples the cover member 170 with the optical control layer 155.

The first optical adhesive layer 151 and the second optical adhesive layer 152 may include an organic insulating material. The first optical adhesive layer 151 and the second optical adhesive layer 152 are made of photo acryl, benzocyclobutene (BCB), polyimide (PI), or polyamide (PA).

The first optical adhesive layer 151 and the second optical adhesive layer 152 may include a transparent optically clear resin layer (OCR) or a transparent optically clear adhesive film (OCA).

The optical control layer 155 may collect light emitted from the display panel 110 in one direction or control the direction of the light. Patterns (not shown) may be disposed on one surface of the optical control layer 155. The first optical adhesive layer 151 may be filled by being disposed on a back surface of the optical control layer 155, and the second optical adhesive layer 152 may be filled by being disposed on an upper surface of the optical control layer 155, thereby preventing or at least reducing the occurrence of defects caused by the step or air gap due to the patterns of the optical control layer 155.

The polarization member 120 may be disposed between the optical adhesive member 150 and the display panel 110. The polarization member 120 can increase outdoor visibility and contrast ratio of images displayed on the display panel 110 by preventing reflection of external light.

The polarization member 120 may be disposed on the display area DA of the display panel 110, but is not limited thereto. The polarization member 120 may be a polarization plate composed of a polarizer and a protective film for protecting the polarizer or disposed on the display panel 110 in a way of being coated with a polarization material for flexibility.

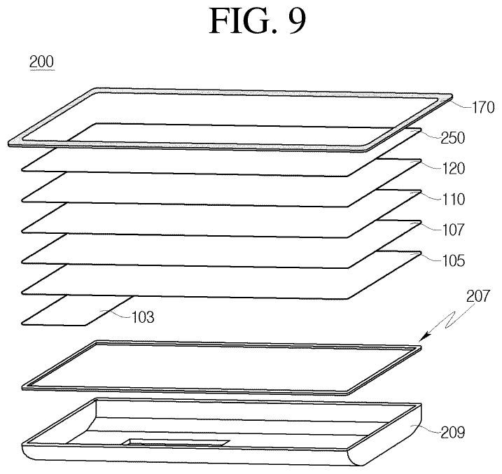

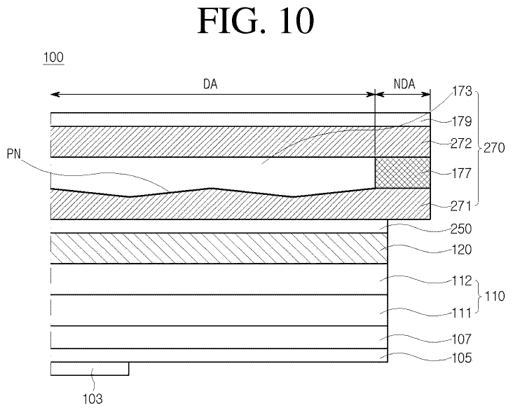

As shown in FIGS. 9 and 10, a display device 200 according to another embodiment of the present specification includes the display panel 110 and a cover member 270 coupled to the display panel 110. The display device 200 may further include the backplate 107 disposed under the display panel 110, the heat dissipation member 105 disposed under the backplate 107, the driving circuit member 103, a housing 209 for storing the display panel 110, and a foam tape 207 for fixing the display panel 110 to the housing 209.

The display device 200 may further include the polarization member 120 disposed on the display panel 110 and an optical adhesive member 250 for coupling the display panel 110 with the cover member 270.

The same reference numerals as the previously described embodiment may be applied to and/or combined with the present embodiment in the same manner. In the following description, overlapping descriptions of the same reference numerals described above may be omitted.

The cover member 270 is disposed on the display panel 110. The cover member 270 is coupled to the display panel 110 through the optical adhesive member 250.

The optical adhesive member 250 may include an organic insulating material. The optical adhesive member 250 may be made of photo acryl, benzocyclobutene (BCB), polyimide (PI), or polyamide (PA). The optical adhesive layer 250 may be a transparent optically clear resin layer (OCR) or a transparent optically clear adhesive film (OCA).

The cover member 270 may have a structure in which a first cover 271 and a second cover 272 are coupled and include the light blocking layer 177 and the resin layer 173. The cover member 270 may further include the coating layer 179 disposed on the second cover 272.

The cover member 270 serves to protect the display panel 110 and is disposed to be exposed to the outside. The cover member 270 may be disposed to cover the entire surface of the display panel 110 with a greater area than the display panel 110 and may accommodate the display panel 110.

The cover member 270 may be partitioned into the display area DA and the non-display area NDA, and the display area DA of the cover member 270 is disposed to overlap the display area DA of the display panel 110 to correspond to the display area DA of the display panel 110. Transparent material layers may be disposed in the display area DA of the cover member 270 so that the image generated by the light emitted from the display area DA of the display panel 110 may be visible by a user.

Specifically, since the first cover 271, the resin layer 173, and the second cover 272 may be disposed in a stacking structure in the display area DA of the cover member 270, the user may perceive the images in the display area DA of the display panel 110 through the display area DA of the cover member 270.

The non-display area NDA of the cover member 270 is disposed to overlap the non-display area NDA of the display panel 110 to correspond to the non-display area NDA of the display panel 110, and the non-display area NDA of the cover member 270 is disposed to be greater than the non-display area NDA of the display panel 110. The non-display area NDA of the cover member 270 may be referred to as a bezel area. The non-display area NDA of the cover member 270 is an area surrounding the display area DA.

The light blocking layer 177 is disposed in the non-display area NDA of the cover member 270 to block various circuit elements, lines, components, and other structures for driving the display panel 110 from being visible to the user.

Specifically, the light blocking layer 177 is disposed to correspond to the non-display area NDA of the cover member 270 between the first cover 271 and the second cover 272. The light blocking layer 177 may be disposed to be in contact with at least a portion of an upper surface of the first cover 271 and to be in contact with a back surface of the second cover 272.

The light blocking layer 177 may be disposed to cover all non-display areas NDA of the display panel 110 excluding the display area DA. Since the display area DA of the display panel 110 corresponds to the display area DA of the cover member 270, the light blocking layer 177 may be disposed to cover the non-display area NDA excluding the display area DA of the cover member 270.

The light blocking layers 277 and 377 described above in FIGS. 8B and 8C may be applied to the light blocking layer 177 disposed inside the cover member 270 implemented in the display device 200.

The first cover 271 and the second cover 272 may be made of a transparent glass or transparent plastic material. For example, the first cover 171 and the second cover 172 may be a film type including an organic material such as polymethylmethacrylate (PMMA), polycarbonate (PC), cycloolefin polymer (COP), polyethylene terephthalate (P), polyimide (PI), or polyaramid (PA) that has impact resistance and light transmittance and may contain an inorganic material such as thin glass or sapphire.

The display device 200 according to another embodiment of the present specification may include the double bonded cover member 270 composed of the first cover 271 and the second cover 272, and the light blocking layer 177 may be provided inside the double bonded cover member 270, thereby preventing the occurrence of the step caused by the light blocking layer 177 and minimizing or at least reducing screen mura or distortion of the display device 200 in the ON state.

In addition, in the display device 200, since the cover member 270 may be formed by double-bonding the first cover 271 and the second cover 272, the surface temperature of the cover member 270 is not easily increased, and the transfer of the surface temperature of the cover member 270 into the display device 200 can be reduced, thereby preventing the degradation of the reliability of the display device 200 and increasing the lifetime of the display device 200.

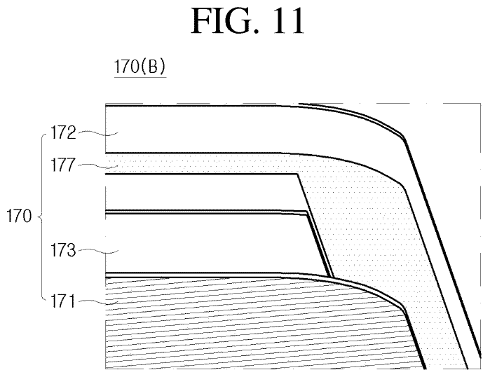

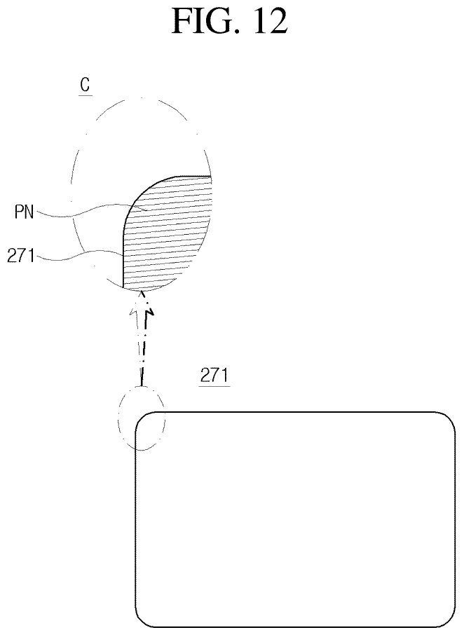

A plurality of light control patterns PN are disposed on one surface of the first cover 271. For example, as shown in FIGS. 11 and 12, the plurality of light control patterns PN may be disposed on the upper surface of the first cover 271. Here, the upper surface of the first cover 271 indicates a surface facing the second cover 272.

The light control pattern PN may be disposed in an engraved, grooved, or concave shape on the upper surface of the first cover 271. Therefore, the upper surface of the first cover 271 may have a plurality of protrusions due to the plurality of light control patterns PN. The protrusions on the upper surface of the first cover 271 may be disposed between the plurality of light control patterns PN. Side portions of the light control pattern PN may have an inclined shape.

The plurality of light control patterns PN may be disposed to be spaced by a predetermined distance from each other. The plurality of light control patterns PN may be disposed to be spaced at regular distances from each other.

The plurality of light control patterns PN may be disposed to have a predetermined inclination with respect to one side of the first cover 271. A groove that is the form of one light control pattern PN may be disposed in a diagonal direction in the upper surface of the first cover 271.

The plurality of light control patterns PN are filled with the resin layer 173 disposed between the first cover 271 and the second cover 272 and coupling the first cover 271 with the second cover 272. Therefore, a gap between the protrusions of the first cover 271 is embedded with and planarized by the resin layer 173.

Although the display device 200 according to another embodiment of the present specification has the plurality of light control patterns PN on the first cover 271 of the cover member 270, the groove or concave shape due to the light control pattern PN and the protrusion of the first cover 271 may be planarized by the resin layer 173, thereby preventing screen distortion defects due to the step.

Since the plurality of light control patterns PN disposed on the upper surface of the first cover 272 serve to control the viewing angle such as condensing light emitted from the display panel 110 toward a driver or condensing the light in an opposite direction, it is not necessary to provide a separate viewing angle control film or optical control film.

In the display device 200 according to another embodiment of the present specification, since the plurality of optical control patterns PN are disposed on the first cover 271 of the cover member 270 and thus there is no need for a separate viewing angle adjustment or control film or optical adjustment film, it is possible to reduce carbon emission, thereby achieving the ESG effect in terms of eco-friendliness.

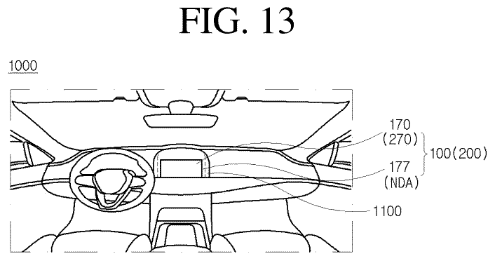

FIG. 13 is a view showing an example of a mobility to which the display device according to the embodiments of the present specification is applied. The mobility is a structure that moves or transports people or objects, and examples of the mobility may include a vehicle, a train, an aircraft, etc. The display device according to the embodiments of the present specification may be applied to an instrument panel disposed at a driver's seat, a center fascia monitor disposed at a central portion, a monitor disposed at a passenger's seat, etc. of a mobility such as a vehicle.

In FIG. 13, a mobility 1000 corresponding to a vehicle is shown as an example, and an example in which the display devices 100 and 200 according to the embodiments of the present specification are applied to the center fascia monitor disposed at the central portion will be described. Referring to FIG. 13, the mobility 1000 adopts the display devices 100 and 200 including the cover members 170 and 270.

Therefore, in the mobility 1000 according to the present specification, since the cover members 170 and 270 are double-bonded by the resin layer, and the light blocking layer 177 is disposed between the double-bonded covers to prevent the occurrence of the step due to the light blocking layer 177, it is possible to minimize the screen distortion of the display devices 100 and 200 in the ON state.

In addition, in the mobility 1000 according to the present specification, since the light blocking layer 177 is disposed between the double-bonded covers, no step occurs even when the colored light blocking layer 177 is applied in the multilayered structure, and thus the colored light blocking layer 177 having the same color as an adjacent component 1100 of the display devices 100 and 200 may be applied. Therefore, it is possible to implement seamless display devices, thereby increasing the user's visibility.

In the mobility 1000 according to the present specification, in the environment in which the mobility 1000 is frequently exposed to the outside, the surface temperatures of the cover members 170 and 270 are not easily increased by the double-bonded cover members 170 and 270, and the transfer of the surface temperatures of the cover members 170 and 270 into the display devices 100 and 200 can be reduced, thereby increasing the lifetimes of the display devices 100 and 200.

Furthermore, in the mobility 1000 in which the user's safety is required, when the cover members 170 and 270 double-bonded by the resin layer according to the present specification are applied, it is possible to minimize shattering of the cover in case of accidents and prevent the withdrawal of internal parts, thereby improving the user's safety.

In the mobility 1000 according to the present specification, when the display device 200 of another embodiment is applied, the light control patterns may be provided on the cover member 270 to provide the same black visual experience as the display screen of the display device 200 in the OFF state.

Furthermore, since the optical control patterns are embedded in the cover member 270 and thus the mobility 1000 to which the display device 200 according to another embodiment of the present disclosure is applied does not require a separate optical control film, it is possible to reduce production energy, reduce carbon emission, and achieve the ESG such as advantages of eco-friendliness or low-power consumption. The embodiments have been above, but are merely illustrative and are not intended to limit the present disclosure. The above-described present specification are not limited by the above-described embodiments and the accompanying drawings, and the features, structures, effects, etc. exemplified in each embodiment can be carried out by being combined or modified. Therefore, the contents related to such combinations and modifications should be construed as being included in the scope of the present disclosure.

According to the display device and the mobility according to the present specification, by arranging the light blocking layer inside the double-bonded cover member, it is possible to prevent the occurrence of the step due to the light blocking layer, thereby preventing the occurrence of screen distortion at the edge of the active area of the display device and improving the clarity of the image quality of the display device.

According to the display device and the mobility according to the present specification, by arranging the double-bonded cover member above the display panel, it is possible to effectively reduce the surface temperature of the display device and minimize the transfer of the surface temperature into the display panel, thereby increasing the lifetime of the display device and improving reliability.

According to the display device and the mobility according to the present specification, by forming the colored light blocking layer disposed inside the double-bonded cover member, it is possible to prevent the boundary line between the display device and the mobilities to which the display device is applied from being visible, thereby increasing the user's visibility.

According to the display device and the mobility according to the present specification, by internalizing the light control pattern in the cover member, the viewing angle can be adjusted without a separate viewing angle adjustment member.

In the present specification, since the manufacturing process for producing the new display device can be reduced as the lifetime of the display device increases when the display device is implemented, it is possible to reduce the generation of greenhouse gases and carbon emission, which may be caused by the manufacturing process, thereby achieving ESG reaching eco-friendliness.

The effects obtainable from the present specification are not limited to the above-described effects, and other effects that are not mentioned will be able to be clearly understood by those skilled in the art to which the present specification pertains from the following description.

What is claimed is:

1. A display device comprising:
a display panel including a display area a non-display area; and
a cover member on the display panel, the cover member including:
a first cover and a second cover that is coupled to the first cover,
a light blocking layer between the first cover and the second cover, the light blocking layer corresponding to the non-display area; and
a resin layer between the first cover and the second cover, the resin layer corresponding to the display area.

2. The display device of claim 1, wherein the light blocking layer is in contact with an upper surface of the first cover and is in contact with a lower surface of the second cover.

3. The display device of claim 1, wherein the light blocking layer extends from an outer edge of the display area to an end of the cover member.

4. The display device of claim 1, wherein a thickness of the first cover is greater than or equal to a thickness of the second cover.

5. The display device of claim 1, wherein the first cover and the second cover are bonded by a resin layer, the resin layer in contact with a side surface of the light blocking layer at an edge of the display area.

6. The display device of claim 1, wherein the light blocking layer surrounds the resin layer in the non-display area.

7. The display device of claim 1, wherein the cover member further comprises a coating layer on an upper surface of the second cover.

8. The display device of claim 1, wherein the light blocking layer comprises a stacking structure of a plurality of layers having different widths in the non-display area.

9. The display device of claim 8, wherein the plurality of layers having different widths have a sequential protrusion structure toward the display area, the sequential protrusion structure is a reverse staircase structure with respect to an upper surface of the first cover.

10. The display device of claim 9, wherein a side surface of the stacking structure of the plurality of layers has an inclination.

11. The display device of claim 8, wherein a width of an uppermost layer of the light blocking layer with the plurality of layers stacked is the greatest, and a width of a lowermost layer of the light blocking layer with the plurality of layers is the smallest.

12. The display device of claim 8, wherein the resin layer extends from the display area to the non-display area and is in contact with at least portions of one end and a back surface of at least one of the plurality of layers.

13. The display device of claim 8, wherein the light blocking layer includes one of white, red, blue, and burgundy or combinations thereof.

14. The display device of claim 1, wherein the light blocking layer includes black ink.

15. The display device of claim 1, further comprising:
an optical adhesive member on a back surface of the cover member, the optical adhesive member including a transparent optically clear resin layer or a transparent optically clear adhesive film, and
a back surface of the first cover and an upper surface of a second substrate of the display panel are coupled through the optical adhesive member.

16. The display device of claim 1, wherein the first cover includes a plurality of optical control patterns on an upper surface thereof.

17. The display device of claim 16, wherein an optical control pattern from the plurality of optical control patterns has an engraved, grooved, or concaved shape.

18. The display device of claim 17, wherein an upper surface of the first cover has a protrusion shape between the plurality of optical control patterns.

19. The display device of claim 18, wherein the resin layer planarizes the plurality of optical control patterns and the protrusion shape.

20. The display device of claim 16, wherein the plurality of optical control patterns are spaced at regular distances from each other, and have a predetermined inclination.

21. A mobility comprising:
a display panel including a display area and a non-display area; and
a cover member including a first cover and a second cover bonded by a resin layer and a light blocking layer between the first cover and the second cover on the display panel,
wherein the light blocking layer has a structure in which a plurality of layers are stacked and includes colored ink different from black.

22. The mobility of claim 21, wherein the light blocking layer has a structure in which the plurality of layers having different widths are stacked and is disposed in the non-display area.

23. The mobility of claim 22, wherein a width of an uppermost layer of the plurality of layers is the greatest, and a width of a lowermost layer of the plurality of layers is the smallest in the structure in which the plurality of layers are stacked.

24. The mobility of claim 21, wherein a plurality of optical control patterns are in an engraved, grooved, or concaved shape on an upper surface of the first cover.

25. The mobility of claim 24, wherein the plurality of optical control patterns are spaced at regular distances from each other and have a predetermined inclination.

26. The mobility of claim 25, wherein the resin layer is between the first cover and the second cover on which the plurality of optical control patterns are disposed and planarize a gap between the first cover and the second cover.
